(19) United States
(12) Patent Application Publication
(10) Pub. No.: US 2024/0222171 A1
(43) Pub. Date: Jul. 4, 2024

(54) SUBSTRATE TREATMENT SYSTEM AND SUBSTRATE TREATMENT METHOD

(71) Applicant: SEMES CO., LTD., Cheonan-si (KR)

(72) Inventors: Young Eun JEON, Ulsan-si (KR); Yun Sang KIM, Seongnam-si (KR); Min Sung JEON, Osan-si (KR); Tae Hwan LEE, Cheonan-si (KR); Sung Min CHOI, Osan-si (KR); Jin Hee HONG, Hwaseong-si (KR); Dong Young JANG, Seongnam-si (KR); Young Jo JIN, Hwaseong-si (KR)

(73) Assignee: SEMES CO., LTD., Cheonan-si (KR)

(21) Appl. No.: 18/542,665

(22) Filed: Dec. 16, 2023

(30) Foreign Application Priority Data
Dec. 28, 2022 (KR) 10-2022-0187370

(51) Int. Cl. H01L 21/67; H01J 37/32

(52) U.S. Cl. CPC H01L 21/67276; H01J 37/3244; H01J 37/32495; H01L 21/67098; H01L 21/67213; H01J 2237/002; H01J 2237/334

(57) ABSTRACT

Proposed are a substrate treatment system and a substrate treatment method. More particularly, a technology capable of realizing a fine etching adjustment and capable of increasing a Unit Per Equipment Hour (UPEH) by reducing time required for a process is provided.

### CROSS REFERENCE TO RELATED APPLICATION

The present application claims priority to Korean Patent Application No. 10-2022-0187370, filed on Dec. 28, 2022, the entire contents of which are herein incorporated by reference.

### BACKGROUND OF THE INVENTION

### Field of the Invention

The present disclosure relates to a substrate treatment system and a substrate treatment method. More particularly, in the present disclosure, a technology capable of realizing a fine etching adjustment and capable of increasing Unit Per Equipment Hour (UPEH) by reducing time required for a process is provided.

### Description of the Related Art

In order to manufacture a semiconductor device, a desired pattern is formed on a substrate by performing various processes such as a photolithography process, an etching process, an ashing process, an ion implantation process, a thin film deposition process, a cleaning process, and so on. Among the various processes, the etching process is a process of removing a selected heating region in a film formed on the substrate, and a wet etching process and a dry etching process are used.

For the dry etching process, a process facility using plasma is used. Generally, in order to form the plasma, an electromagnetic field is generated in an inner space of a chamber, and the electromagnetic field excites a process gas provided in the chamber into a plasma state.

Plasma refers to an ionized gaseous state composed of ions or electrons, radicals, and so on. Plasma may be generated by a very high temperature, a strong electric field, or an RF electromagnetic field. In a semiconductor device manufacturing process, the etching process may be performed using plasma.

In a conventional plasma process facility, since a plasma etching process is performed simultaneously with an adsorption process and an etching process, there is a problem that adjustment of fine etching is difficult to perform. In addition, there is a problem that an attack and a diffusion roughness change of a target underlayer film occur. Furthermore, since a process time through the conventional plasma process facility requires more than 60 minutes per process, there is a problem that a Unit Per Equipment Hour (UPEH) is reduced.

### SUMMARY OF THE INVENTION

Accordingly, the present disclosure has been made keeping in mind the above problems occurring in the related art, and an objective of the present disclosure is to provide a method of increasing a Unit Per Equipment Hour (UPEH) by assigning a substrate treatment process task for process characteristics through a substrate treatment system configured by combining a dual process facility that individually performs an adsorption process through plasma treatment and an etching process through thermal treatment and a single process facility that integrates and performs the adsorption process and the etching process in a single apparatus.

Particularly, an objective of the present disclosure is to solve a problem of difficulty in adjusting fine etching due to the adsorption process and the etching process that are simultaneously performed in a conventional plasma process facility.

The objectives of the present disclosure are not limited thereto, and other objectives and other advantages of the present disclosure will be understood from the following description.

According to an embodiment of the present disclosure, there is provided a substrate treatment system including: a dual process facility including at least one plasma process apparatus configured to perform an adsorption process on a substrate through plasma treatment and at least one thermal treatment apparatus configured to perform an etching process on the substrate through thermal treatment; a substrate transfer apparatus configured to transfer the substrate between the plasma process apparatus and the thermal treatment apparatus; and a control apparatus configured to schedule a substrate treatment process of a repetitive cycle of the adsorption process and the etching process and to assign a substrate treatment process task for the dual process facility, wherein the dual process facility is configured such that the number of plasma process apparatuses is determined and the number of thermal treatment apparatuses is determined according to a process time ratio between the adsorption process and the etching process.

The substrate treatment system may further include a single process facility including at least one substrate process apparatus configured to perform the adsorption process on the substrate through the plasma treatment and to perform the etching process on the substrate through the thermal treatment, wherein the control apparatus may be configured to schedule the substrate treatment process by distinguishing the dual process and the single process facility, and may be configured to assign the substrate treatment process task to the dual process facility and the single process facility.

Furthermore, the control apparatus may be configured to schedule the substrate treatment process by distinguishing the dual process facility and the single process facility according to a type of process gas input during the plasma treatment of the substrate, and may be configured to assign the substrate treatment process task to the dual process facility and the single process facility.

Furthermore, the control apparatus may be configured to schedule the substrate treatment process by distinguishing the dual process facility and the single process facility according to a thermal treatment process time of the substrate, and may be configured to assign the substrate treatment process task to the dual process facility and the single process facility.

As an example, the control apparatus may be configured to determine a weighting of the substrate treatment process task assigned to each of the dual process facility and the single process facility, may be configured to reschedule the substrate treatment process task assigned to each of the dual process facility and the single process facility on the basis of the weighting, and may be configured to bypass the substrate treatment process task assigned to the dual process facility to the single process facility, thereby being capable of reassigning the substrate treatment process task.

As an example, the plasma process apparatus of the dual process facility may include: a plasma process chamber providing a plasma treatment space for the substrate; a substrate supporting unit configured to support the substrate; a plasma generation unit configured to induce plasma on the plasma treatment space; and a gas supply unit configured to supply a process gas to the plasma treatment space.

As an example, the plasma process apparatus of the dual process facility may further include an ion blocker disposed at an upper portion of the plasma treatment space of the plasma process chamber and configured to partition an upper plasma space and a lower plasma space, the ion blocker being configured to filter ions and to diffuse radicals.

As an example, the thermal treatment apparatus of the dual process facility may include: a thermal treatment chamber providing a thermal treatment space for the substrate; a substrate supporting unit configured to support the substrate; a heat source unit disposed at an upper portion of the thermal treatment space and configured to provide a heat source for heating the substrate; a cooling unit for cooling the substrate; and a gas supply unit providing a process gas to the thermal treatment space.

As an example, the substrate treatment apparatus may include: a process chamber providing a treatment space for the substrate; a substrate supporting unit configured to support the substrate; a plasma generation unit configured to induce plasma on the treatment space; a heat source unit disposed at an upper portion of the treatment space and configured to provide a heat source for heating the substrate; a cooling unit for cooling the substrate; and a gas supply unit configured to supply a process gas to the treatment space.

The plasma generation unit may include: a transparent window disposed on the upper portion of the treatment space; a transparent electrode formed on the window; and a power supply part configured to supply an RF power to the transparent electrode.

Furthermore, the heat source unit may be disposed on an upper portion of the window of the plasma generation unit, and may include a laser generator configured to heat the substrate by emitting laser or a microwave generator configured to heat the substrate by emitting microwaves.

In addition, according to the present disclosure, there is provided a substrate treatment method including: a process task assignment process in which a control apparatus schedules a substrate treatment process of a repetitive cycle of an adsorption process and an etching process on a substrate and assigns a substrate treatment process task to a plasma process apparatus and a thermal treatment apparatus of a dual process facility; and a process performing process in which the control apparatus controls a substrate transfer apparatus so that the substrate is transferred between the plasma process apparatus and the thermal treatment apparatus of the dual process facility and the control apparatus controls the plasma process apparatus so that the adsorption process is performed and controls the thermal treatment apparatus so that the etching process is performed.

The substrate treatment method may further include a treatment process determination process in which a type of a process gas input during plasma treatment on the substrate is determined, wherein, in the process task assignment process, the substrate treatment process task may be assigned by distinguishing the dual process facility and a single process facility according to the type of the process gas input during the plasma treatment on the substrate.

As an example, in the process task assignment process, when the plasma treatment on the substrate is performed by using a process gas containing a F-type (fluorine type) process gas or a H-type (hydrogen type) process gas, the substrate treatment process task may be assigned to the single process facility.

As an example, in the process task assignment process, when the plasma treatment on the substrate is performed by using a process gas containing a CF-type (fluorocarbon type) process gas or a NF3-type (nitrogen trifluoride type) process gas, the substrate treatment process task may be assigned to the dual process facility.

The substrate treatment method may further include a treatment process determination process in which a thermal treatment process time on the substrate is determined, wherein, in the process task assignment process, the substrate treatment process task may be assigned by distinguishing the dual process facility and a single process facility according to the thermal treatment process time on the substrate.

As an example, in the process task assignment process, when thermal treatment on the substrate is performed with the thermal treatment process time shorter than a reference time, the substrate treatment process task may be assigned to the single process facility.

As an example, in the process task assignment process, when thermal treatment on the substrate is performed with the thermal treatment process time longer than a reference time, the substrate treatment process task may be assigned to the dual process facility.

Furthermore, the substrate treatment method may further include: a process situation monitoring process in which a substrate treatment process performance situation of each of the dual process facility and a single process facility is monitored; a weighting determination process in which a weighting for a substrate treatment task of each of the dual process facility and the single process facility is determined on the basis of the substrate treatment process performance situation and the substrate treatment process task assigned for each of the dual process facility and the single process facility; a rescheduling process in which the substrate treatment process task for the dual process facility having a relatively high weighting and for the single process facility having a relatively low weighting is rescheduled; and a process treatment task reassignment process in which the substrate treatment process task of the dual process facility is bypassed and assigned to the single process facility.

According to an embodiment of the present disclosure, there is provided a substrate treatment system including: a dual process facility including at least one plasma process apparatus configured to perform an adsorption process on a substrate through plasma treatment and at least one thermal treatment apparatus configured to perform an etching process on the substrate through thermal treatment, the dual process facility being configured such that the number of plasma process apparatuses is determined and the number of thermal treatment apparatuses is determined according to a process time ratio between the adsorption process and the etching process; a single process facility including at least one substrate process apparatus configured to perform the adsorption process on the substrate through the plasma treatment and to perform the etching process on the substrate through the thermal treatment; a substrate transfer apparatus configured to transfer the substrate to the plasma process apparatus and the thermal treatment apparatus of the dual process facility and to the substrate treatment apparatus of the single process facility; and a control apparatus configured to schedule a substrate treatment process by distinguishing the dual process facility and the single process facility, to assign a substrate treatment process task by distinguishing the dual process facility and the single process facility according to a type of a process gas input during the plasma treatment and a thermal treatment process time on the substrate, to determine a weighting for a substrate treatment task assigned to each of the dual process facility and the single process facility, and to reassign the substrate treatment task by bypassing the substrate treatment task assigned to the dual process facility to the single process facility on the basis of the weighting.

In the present disclosure as described above, a Unit Per Hour (UPEH) may be increased by assigning a substrate treatment process task by process characteristics through the substrate treatment system configured by combining the dual process facility that individually performs the adsorption process through the plasma treatment and the etching process through the thermal treatment and the single process facility that integrates and performs the adsorption process and the etching process.

Particularly, the fine etching may be easily adjusted by separating and performing the adsorption process and the etching process from a separate apparatus or by integrating and performing the adsorption process and the etching process in one apparatus according to the process characteristics.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a basic configuration of an example of a substrate treatment system according to the present disclosure;

FIG. 2 is a view illustrating an embodiment of a plasma process apparatus in a dual process facility of the substrate treatment system according to the present disclosure;

FIG. 3 is a view illustrating an embodiment of a thermal treatment apparatus in the dual process facility of the substrate treatment system according to the present disclosure;

FIG. 4 is a view illustrating an embodiment of a substrate treatment apparatus in a single process facility of the substrate treatment system according to the present disclosure;

FIG. 5 to FIG. 7 are views illustrating embodiments of the substrate treatment system according to the present disclosure;

FIG. 8 is a view illustrating an embodiment of a control apparatus of the substrate treatment system according to the present disclosure;

FIG. 9 is a flowchart illustrating an embodiment of a substrate treatment method according to the present disclosure;

FIG. 10 is a flowchart illustrating an embodiment of the substrate treatment method using the dual process facility according to the present disclosure;

FIG. 11 is a view illustrating an embodiment of performing a substrate treatment process task by distinguishing the dual process facility and the single process facility according to a type of process gas in the substrate treatment method according to the present disclosure;

FIG. 12 is a view illustrating an embodiment of performing the substrate treatment process task by distinguishing the dual process facility and the single process facility according to a thermal treatment process time in the substrate treatment method according to the present disclosure; and

FIG. 13 is an example of bypassing the substrate treatment process task in the substrate treatment method according to the present disclosure.

### DETAILED DESCRIPTION OF THE INVENTION

Hereinafter, exemplary embodiments of the present disclosure will be described in detail with reference to the accompanying drawings, but the present disclosure is not limited or restricted to the embodiments.

In order to explain the present disclosure, the operational advantages of the present disclosure, and the objectives achieved by the practice of the present disclosure, the embodiments of the present disclosure are exemplified below and will be described with reference thereto.

First, the terms used in this application are only used to describe specific embodiments, and are not intended to limit the present disclosure, and a singular expression may include a plural expression unless the context clearly indicates otherwise. In addition, it should be understood that in the present disclosure, terms such as “comprise” or “have” are intended to designate that a feature, number, step, operation, component, part, or combination thereof described in the specification exists, and do not preclude the possibility of addition or existence of one or more other features or numbers, steps, operations, components, parts, or combinations thereof.

In describing the present disclosure, when it is determined that a detailed description of a related known configuration or function may obscure the gist of the present disclosure, the detailed description thereof will be omitted.

The present disclosure relates to a substrate treatment system and a substrate treatment method. More particularly, in the present disclosure, a technology capable of realizing a fine etching adjustment and capable of increasing a Unit Per Equipment Hour (UPEH) by reducing time required for a process is provided.

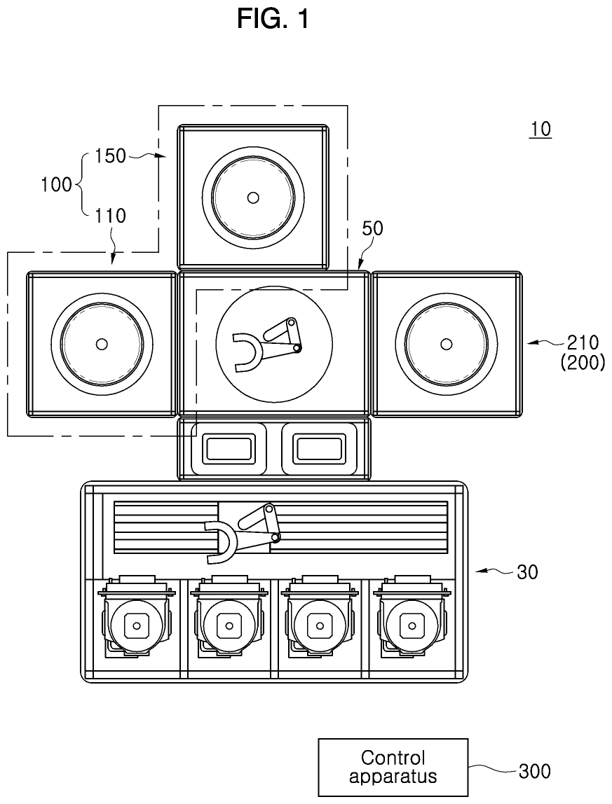

FIG. 1 is a view illustrating a basic configuration of an example of a substrate treatment system according to the present disclosure.

A substrate treatment system 10 may include a dual process facility 100, a single process facility 200, an index module 30, and so on.

In the dual process facility 100, an apparatus performing an adsorption process through plasma treatment on a substrate and an apparatus performing an etching process through thermal treatment on a substrate may be separately configured.

As an example, the dual process facility 100 may include a plasma process apparatus 110, a thermal treatment apparatus 150, and so on.

By using the dual process facility 100, when the etching process on the substrate is performed, the adsorption process through the plasma process apparatus 110 and the etching process through the thermal treatment apparatus 150 may be performed in a repetitive cycle.

Various plasma process apparatuses such as a Capacitively Coupled Plasma (CCP) apparatus, an Inductively Coupled Plasma (ICP) apparatus, a microwave-type plasma apparatus, and so on may be applied as the plasma process apparatus 110 of the dual process facility 100.

The single process facility 200 may perform the adsorption process through the plasma treatment and the etching process through the thermal treatment in one apparatus.

As an example, the single process facility 200 may include a substrate treatment apparatus 210 in which a plasma process apparatus and a thermal treatment apparatus are integrated.

The adsorption process through the plasma treatment and the etching process through the thermal treatment may be performed in the single substrate treatment apparatus 210 by using the single process facility 200.

The index module 30 may supply the substrate to the dual process facility 100 or the single process facility 200.

A control apparatus 300 may schedule the substrate treatment process, and may assign a substrate treatment process task to the dual process facility 100 and the single process facility 200.

The dual process facility 100 and the single process facility 200 will be described in more detail with reference to each embodiment.

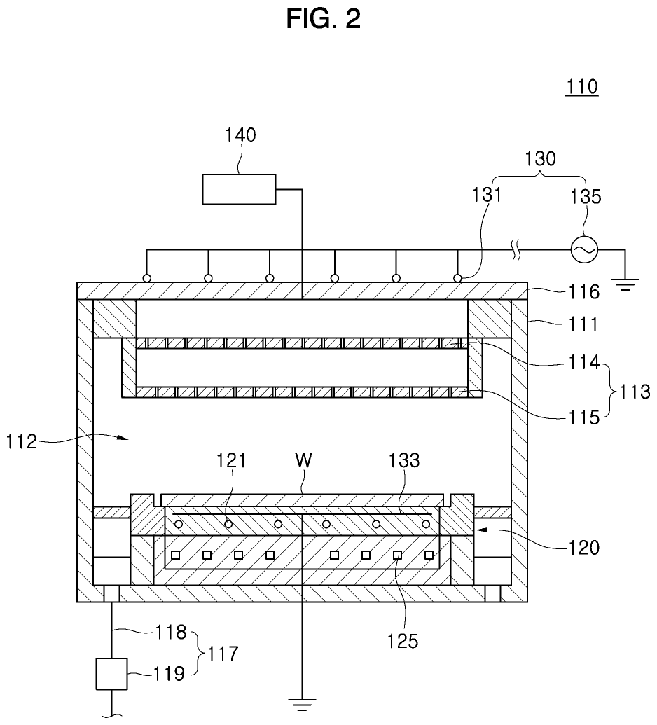

As an exemplary embodiment in which a Capacitively Coupled Plasma (CCP) method is applied in relation to the plasma process apparatus 110 of the dual process facility 100, an embodiment of a plasma process apparatus in a dual process facility of the substrate treatment system according to the present disclosure is illustrated in FIG. 2.

The plasma process apparatus 110 may include a plasma process chamber 111, a substrate supporting unit 120, a plasma generation unit 130, a gas supply unit 140, and so on. Furthermore, an ion blocker 113 may be provided in the plasma process chamber 111 of the plasma process apparatus 110.

The plasma process chamber 111 may provide a plasma treatment space 112 for performing the plasma treatment process on a substrate W. As an example, the plasma process chamber 111 may be a cylindrical vacuum chamber.

A chamber cover 116 is disposed on an upper portion of the plasma process chamber 111, so that the plasma treatment space 112 of the plasma process chamber 111 may be sealed.

A door means (not illustrated) for entering and exiting the substrate W may be mounted on a side wall of the plasma process chamber 111. The substrate W is capable of being brought in and out of the plasma treatment space 112 of the plasma process chamber 111 by the door means.

An exhaust part 117 may be mounted on a lower portion of the plasma process chamber 111. The exhaust part 117 may include an exhaust pipe 118, a vacuum pump 119 and so on. The exhaust part 117 may use the vacuum pump 119 such as a turbo molecular pump so that a pressure in the plasma treatment space 112 of the plasma process chamber 111 is adjusted to a pressure of a desired vacuum level. In addition, the exhaust part 117 may discharge process by-products and residual process gases generated in the plasma process chamber 111.

A part in contact with the process gas, such as a wall portion of the plasma process chamber 111, may be formed of a material such as aluminum ceramic (Al Ceramic).

The substrate supporting unit 120 may be disposed in the plasma treatment space 112 of the plasma process chamber 111. The substrate supporting unit 120 may support the substrate W.

The substrate supporting unit 120 may include an electrostatic chuck (ESC) configured to adsorb and support the substrate by an electrostatic force. According to a situation, the substrate supporting unit 120 may include various substrate supporting means capable of fixing and supporting the substrate by mechanical clamping or supporting the substrate by a vacuum adsorption force.

The substrate supporting unit 120 may adjust the temperature of the substrate when the plasma process treatment on the substrate is performed. For this purpose, the substrate supporting unit 120 may be provided with a heating member 121 and a cooling member 125. For example, the temperature of the substrate may be increased and adjusted to a set high temperature by using the heating member 121. In addition, the temperature of the substrate may be lowered and adjusted to a set low temperature by using the cooling member 125.

The plasma generation unit 130 may activate plasma in the plasma treatment space 112 of the plasma process chamber 111.

The plasma generation unit 130 may include an upper electrode 131, a lower electrode 133, an RF power supply part 135, and so on.

The upper electrode 131 may include a high frequency (RF) antenna. The antenna may have a planar coil shape. The chamber cover 116 may include a dielectric window having a circular plate shape. The dielectric window may include a dielectric material. For example, the dielectric window may include aluminum oxide Al2O3. The dielectric window may have a function of transmitting power from the antenna to the inside of the plasma process chamber 111.

For example, the upper electrode 131 may include coils in a spiral shape or a concentric shape. Here, the number, the arrangement, and so on of the coils may be appropriately changed as required.

The RF power supply part 135 may apply a plasma source power to the upper electrode 131. The RF power supply part 135 may generate a high frequency (RF) signal and may apply the high frequency (RF) signal to the upper electrode 131.

The lower electrode 133 may be disposed inside the substrate supporting unit 120. The lower electrode 133 may be grounded or connected to a bias power source.

The gas supply unit 140 may supply a process gas to the inside of the plasma process chamber 111, and may also supply a carrier gas to the inside of the plasma process chamber 111 in addition to the process gas.

As a process gas, various process gases may be selected according to characteristics of a target substrate that is processed with plasma. Since a part in contact with the process gas such as a wall part of the plasma process chamber 111 is formed of a material such as aluminum ceramic (Al Ceramic), a F-type (fluorine-type) gas or a H-type (hydrogen-type) gas may be excluded or a gas in which the F-fluorine-type gas or H-type gas is minimized may be used. That is, in order to prevent corrosion of the part in contact with the process gas such as the wall part of the plasma process chamber 111, the process gas input during the plasma treatment may be selected.

The carrier gas is a gas that does not react with the process gas and does not react with the upper surface of the substrate, and may include an inert gas such as argon (Ar) and so on.

Furthermore, the gas supply unit 140 may include a Flow Rate Controller (FRC), thereby being capable of adjusting the supply quantity of the process gas and the supply quantity of the carrier gas. As an example, the FRC may include a Mass Flow Controller (MFC).

The ion blocker 113 is disposed in an upper space inside the plasma process chamber 111, and may partition the plasma treatment space 112. As an example, the ion blocker 113 may form an upper plasma space on an upper portion of the ion blocker 113, and may form a lower plasma space on the upper portion of the substrate.

As an example, the ion blocker 113 may include an upper plate 114 and a lower plate 115, and may include a diffusion space provided between the upper plate 114 and the lower plate 115.

A plurality of gas inlet holes as penetration holes in which gas from the upper plasma space is introduced into the diffusion space may be provided in the upper plate 114. A plurality of gas discharge holes as penetration holes through which gas in the diffusion space is diffused to the lower plasma space may be provided in the lower plate 115.

The plurality of gas inlet holes provided in the upper plate 114 and the plurality of gas discharge holes provided in the lower plate 115 may be disposed such that imaginary extension lines are not aligned with each other. That is, imaginary extension holes for the gas inlet holes of the upper plate 114 are blocked by contacting an upper surface of the lower plate 115, and imaginary extension holes for the gas discharge holes of the lower plate 115 are blocked by contacting a lower surface of the upper plate 114.

The number, the arrangement form, and so on of the gas inlet holes of the upper plate 114 and the gas discharge holes of the lower plate 115 may be variously modified as required.

By filtering ions through the structure of the ion blocker 113, radicals may be diffused to the surface of the substrate.

When the plasma treatment process is performed on the substrate on the substrate by using the plasma process apparatus 110, radicals for etching may be adsorbed to the substrate.

Next, the thermal treatment apparatus 150 of the dual process facility 100 will be described. The thermal treatment apparatus 150 may use at least one heat source emit so as to emit heat among various heat sources such as a flash lamp, a laser generator, or a microwave generator, and may perform an etching process through thermal treatment on the substrate by emitting heat.

As an example, the flash lamp may provide light as heating energy. The laser generator may provide a laser as heating energy. The microwave generator may provide a microwave as heating energy.

A heat source using a lamp may be applied to the thermal treatment apparatus 150 of the dual process facility 100 so that the thermal treatment apparatus 150 is suitable for performing the heating process for a long time. That is, in the dual process facility 100, since the number of thermal treatment apparatuses 150 may be increased compared to the number of plasma process apparatuses 110, a substrate treatment process operation that requires the thermal treatment process to be performed for a long time is capable of being performed through the dual process facility 100.

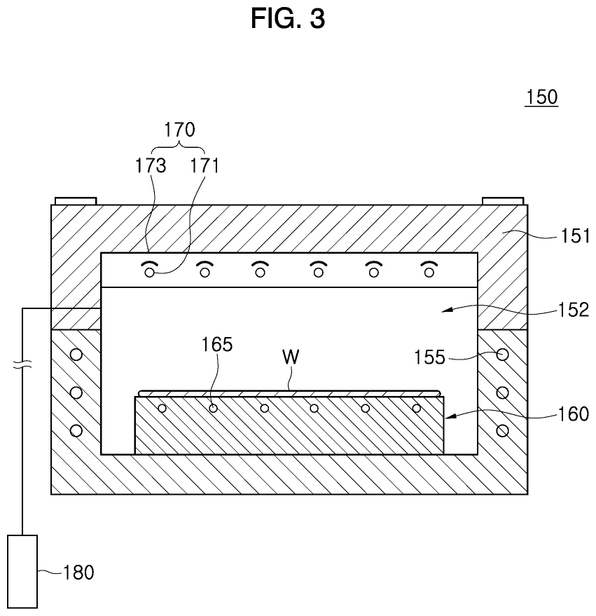

As an example of applying a heat source of an IR lamp to the thermal treatment apparatus 150 of the dual process facility 100, FIG. 3 illustrates an embodiment of the thermal treatment apparatus in the dual process facility of the substrate treatment system according to the present disclosure.

The thermal treatment apparatus 150 may include a thermal treatment chamber 151, a substrate supporting unit 160, a heat source unit 170, a gas supply unit 180, and so on.

The thermal treatment chamber 151 may provide a thermal treatment space 152 for performing the thermal treatment process on the substrate W.

The substrate supporting unit 160 may be disposed in the thermal treatment space 152 of the thermal treatment chamber 151. The substrate W may be seated and supported on the substrate supporting unit 160.

The heat source unit 170 may be disposed on an upper portion of the thermal treatment space 152 of the thermal treatment chamber 151.

The heat source unit 170 may include an IR lamp 171 and a reflective cover 173. In an embodiment, the heat source unit 170 may include the IR lamp 171 that includes a plurality of IR lamps 171 arranged to correspond to the size of the substrate W, and may include the reflective cover 173 that includes a plurality of reflective covers 173 arranged such that each IR lamp 171 concentrates and emits light.

The IR lamp 171 may emit light energy, and the light energy emitted from the IR lamp 171 may be provided to the substrate W.

Each reflective cover 173 is positioned above each IR lamp 171, and may collect light emitted from the IR lamp 171 and may emit light toward the substrate W.

A temperature of the substrate W may be rapidly increased to a set temperature range by being rapidly heated by light energy emitted from the heat source unit 170.

In addition, the thermal treatment apparatus 150 may further include cooling units 155 and 165.

The cooling unit 165 may be disposed in the substrate supporting unit 160, thereby cooling the substrate W. As an example, the cooling unit 165 may include a cooling flow path disposed in the substrate supporting unit 160, and may include a refrigerant supply part supplying a refrigerant to the cooling flow path.

In addition, since the cooling unit 155 is disposed on a side wall of the thermal treatment chamber 151, the temperature of the thermal treatment chamber 151 is capable of being prevented from increasing to a predetermined level, and the temperature of the thermal treatment space 152 of the thermal treatment chamber 151 is capable of being decreased, thereby being capable of more rapidly cooling the substrate W.

The gas supply unit 180 may supply an environment-forming gas for forming a thermal treatment environment on the thermal treatment space 152 of the thermal treatment chamber 151, and may supply a purge gas for etching the substrate through the thermal treatment. As an example, an inert gas such as N2, Ar, He, and so on may be applied as the environment-forming gas so that a reaction of the environment-forming gas with other gas is not induced and the environment-forming gas does not react with the surface of the substrate.

The thermal treatment apparatus 150 may shorten the process time by rapidly thermal treating the substrate W, and may promote etching uniformity by heating and cooling the substrate W.

In the dual process facility 100 described above, the plasma process apparatus 110, which performs the adsorption process through the plasma treatment on the substrate, and the thermal treatment apparatus 150, which performs the etching process through the thermal treatment, are configured such that the plasma process apparatus 110 and the thermal treatment apparatus 150 are separated from each other. Furthermore, the fine etching on the substrate is capable of being effectively controlled by performing the adsorption process through the plasma treatment and the etching process through the thermal treatment in repeated cycles.

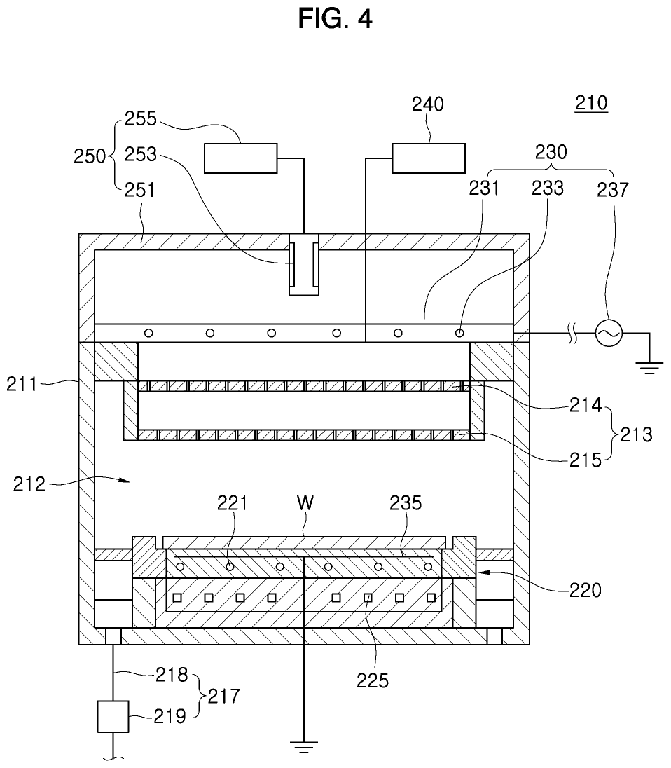

In relation to the substrate treatment apparatus 210 of the single process facility 200, FIG. 4 illustrates an embodiment of the substrate treatment apparatus in the single process facility of the substrate treatment system according to the present disclosure.

In the present disclosure, the substrate treatment apparatus 210 of the single process facility 200 is a configuration in which the dual process facility 100 described above is integrated, so that the description of the parts that are the same or similar to the dual process facility 100 will be omitted or briefly described.

The substrate treatment apparatus 210 may include a configuration for performing the plasma treatment on the substrate, and may selectively include a configuration for performing the plasma treatment in various manners, such as a Capacitively Coupled Plasma (CCP) configuration, an Inductively Coupled Plasma (ICP) configuration, a microwave-type plasma configuration, and so on. In the present embodiment, the CCP type apparatus is described as the substrate treatment apparatus 210, but there is no limitation.

The substrate treatment apparatus 210 may include a process chamber 211, a substrate supporting unit 220, a plasma generation unit 230, a gas supply unit 240, a heat source unit 250, and so on.

The process chamber 211 may provide a treatment space 212 for performing a treatment process on the substrate. Here, the treatment space 212 of the process chamber 211 may be a space in which a space for performing the plasma treatment and a space for performing the thermal treatment are integrated.

An exhaust part 217 may be provided on a lower portion of the process chamber 211. The exhaust part 217 may include an exhaust pipe 218, a vacuum pump 219 and so on. The exhaust part 217 may adjust an internal vacuum pressure of the process chamber 211, and may discharge process by-products and remaining process gases.

A part, such as a wall part of the process chamber 211, in contact with the process gas may be formed of a material having corrosion resistance to a F-type (fluorine type) process gas or a H-type (hydrogen type) process gas. For example, in the plasma process apparatus 110 of the dual process facility 100 described above, a part in contact with the process gas such as the wall part of the plasma process chamber 111 may be formed of a material such as aluminum ceramic (Al Ceramic). In contrast, in the substrate treatment apparatus 210 of the single process facility 200, a part in contact with the process gas such as the wall part of the process chamber 211 is formed of a material having corrosion resistance to the F-type process gas of the H-type process gas, so that the plasma treatment through the F-type process gas or the H-type process gas is capable of being performed. The substrate supporting unit 220 may be disposed on the lower portion of the treatment space 212 of the process chamber 211. The substrate supporting unit 220 may support the substrate W.

The substrate unit supporting 220 may include an electrostatic chuck (ESC) configured to adsorb and support the substrate W by using an electrostatic force. Alternatively, the substrate supporting unit 220 may include various substrate supporting means capable of fixing and supporting the substrate by mechanical clamping or adsorbing and supporting the substrate by a vacuum pressure.

The substrate supporting unit 220 may be provided with a heating member 221, a cooling member 225, and so on, thereby being capable of adjusting the temperature of the substrate W.

The plasma generation unit 230 may activate plasma in the treatment space 212 of the process chamber 211.

The plasma generation unit 230 may include an upper electrode 233, a lower electrode 235, an RF power supply part 237, and so on.

The upper electrode 233 may be provided in a window 231. The window 231 may be provided with a transparent material in which light or microwaves emitted from the heat source unit 260 that will be described later is capable of being transmitted to the substrate W without loss. In an embodiment, the window 231 may be formed of a material having corrosion resistance. As an example, the window 231 may be formed of quartz.

The upper electrode 233 may be formed inside the window 231 or may be formed on an upper surface of the window 231. As an example, the upper electrode 233 may be formed of a Transparent Conductive Oxide (TCO) film.

In order to heat the substrate W, the TCO film of the upper electrode 233 may be provided such that the TCO film has a thickness in which light or microwaves emitted from the heat source unit 250 are capable of being transmitted through the TCO film. As an example, the TCO film may be an Indium Tin Oxide (ITO) film. In addition, the TCO film may be formed of any one or more of AZO, FTO, ATO, SnO2, Zno, IrO2, RuO2, graphene, a metal nanowire, CNT, or mixtures thereof, or multiple layers thereof.

The RF power supply part 237 may apply a plasma source power to the upper electrode 233. The RF power supply part 237 may generate a high frequency (RF) signal and may apply the high frequency (RF) signal to the upper electrode 233.

The lower electrode 235 may be disposed inside the substrate supporting unit 220. The lower electrode 235 may be grounded or connected to a bias power source.

The gas supply unit 240 may supply the process gas to the inside of the process chamber 211. In addition to the process gas, the gas supply unit 240 may supply a carrier gas to the inside of the process chamber 211.

As a process gas, various process gases may be selected according to characteristics of a target substrate that is processed with plasma. In an embodiment, as a process gas, a gas in which a CF-type (fluorocarbon) gas or a NF3-type (nitrogen trifluoride) gas is excluded or minimized may be used. That is, since the window 231 formed of quartz is provided so that heat emitted from the heat source unit 260 is properly transferred to the substrate W, the window 231 is corroded when the CF-type gas or the NF3-type gas is used as the process gas. Therefore, in the substrate treatment apparatus 210 of the single process facility 200, the use of CF-type process gas or the NF3-type process gas may be avoided.

Furthermore, an ion blocker 213 may be disposed at an upper portion of the treatment space 212 of the process chamber 211. The ion blocker 213 may partition the process chamber 211 and the treatment space 212 from each other. As an example, the ion blocker 213 may form an upper plasma space on an upper portion of the ion blocker 113, and may form a lower plasma space on the upper portion of the substrate.

As an example, the ion blocker 213 may include an upper plate 214 provided with a gas inlet hole, and may include a lower plate 215 provided with a gas discharge hole. Furthermore, the ion blocker 213 may include a diffusion space provided between the upper plate 214 and the lower plate 215.

The heat source unit 250 may be disposed above the window 231.

The heat source unit 250 may heat the substrate W by emitting heat. The heat source unit 250 may include various heat source configurations such as a flash lamp, a laser generator, a microwave generator, and so on. As an example, the flash lamp may provide light as heating energy. The laser generator may provide a laser as heating energy. The microwave generator may provide a microwave as heating energy.

Since the single process facility 200 integrates the adsorption process through the plasma treatment and the etching process through the thermal treatment in one substrate treatment apparatus 210, it is appropriate to perform the thermal treatment process relatively briefly compared to the thermal treatment process in the dual process facility 100. Accordingly, a heat source such as laser, microwaves, or the like may be used in the heat source unit 250 of the substrate treatment apparatus 210 so as to be suitable for performing the thermal treatment process through repeated control of such as a pulse waveform (PWM).

In the present embodiment, an example in which microwaves are used as the heat source is described. The heat source unit 250 may include a waveguide 253, a microwave generator 255, and so on.

A cover 251 may cover the upper portion of the window 231, thereby sealing a space. The waveguide 253 may be disposed such that the waveguide 253 penetrates the cover 251. As an example, the waveguide 253 may be disposed at a position corresponding to a center of the window 231.

The waveguide 253 may transmit microwaves to the treatment space 212 of the process chamber 211. The microwave generator 255 may generate electromagnetic waves of a corresponding microwave band. The microwaves generated in the microwave generator 255 may be propagated to the treatment space 212 of the process chamber 211 through the waveguide 253.

Since wavelength of the microwaves is much longer than a thickness and a space of a metal wiring layer of a semiconductor chip, a depth at which the microwaves penetrate into a metal material is less than several μm. Since the surface of the substrate is heated by a microwave thermal treatment through the heat source unit 250, the temperature of the surface of the substrate is capable of being rapidly increased to a target temperature.

Particularly, since the surface of the substrate is selectively heated by the thermal treatment through microwaves, the temperature increase speed and the cooling speed are fast, and the surface of the substrate is capable of being heated to the target temperature within a short time, so that the process time may be shortened.

The single process facility 200 described above may efficiently adjust the fine etching of the substrate by repeatedly performing the adsorption process through the plasma treatment and the etching process through the thermal treatment.

In the present disclosure, the substrate treatment system may be formed by various combinations of the dual process facility 100 and the single process facility 200 described above.

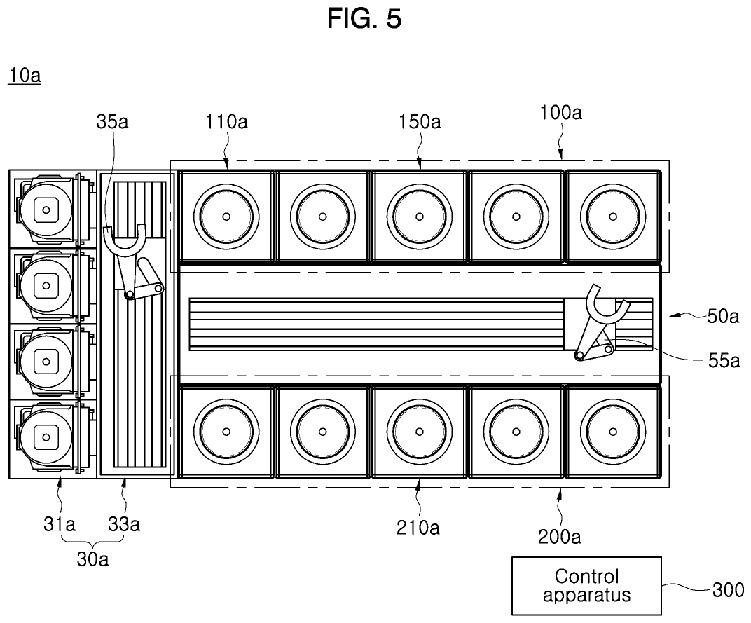

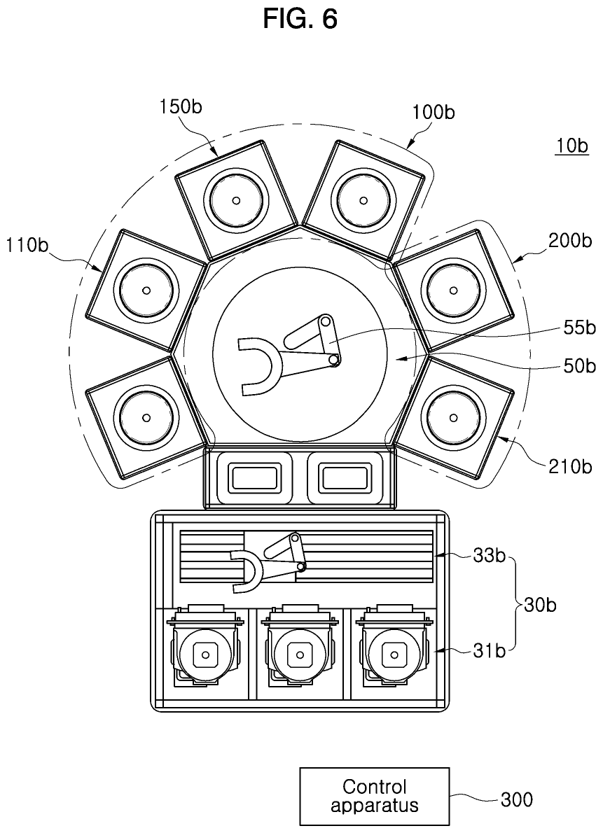

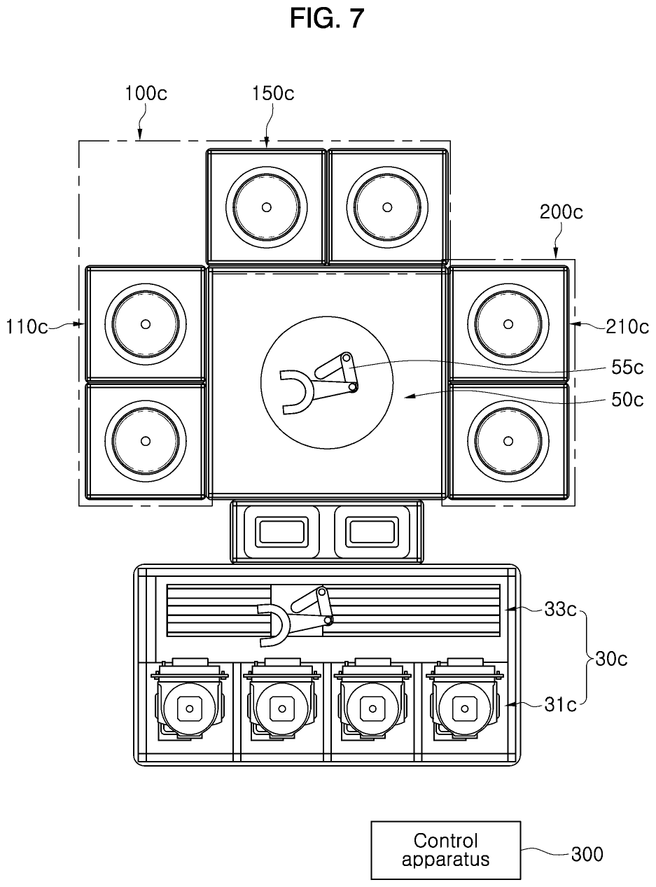

FIG. 5 is a view illustrating an embodiment of the present disclosure in which the substrate treatment system of a hyperspace type is illustrated, FIG. 6 is a view illustrating an embodiment of the present disclosure in which the substrate treatment system of a cluster type is illustrated, and FIG. 7 is a view illustrating an embodiment of the present disclosure in which the substrate treatment system of a puritas type is illustrated.

In the present embodiment, a form in which a dual process facility 100a and a single process facility 200a are arranged along a longitudinal direction with respect to a substrate transfer apparatus 50a is named as a hyperspace type, a form in which a dual process facility 100b and a single process facility 200b are arranged along a circumferential direction with respect to a substrate transfer apparatus 50b is named as a cluster type, and a form in which a dual process facility 100c and a single process facility 200c are disposed on a left portion, a right portion, and an upper portion of a circumference of the substrate transfer apparatus 50c is named as a puritas type.

The substrate treatment systems 10a, 10b, and 10c may be respectively configured by combining dual process facilities 100a, 100b, and 100c with single process facilities 200a, 200b, and 200c.

In the hyperspace-type substrate treatment system 10a in FIG. 5, a plurality of dual process facilities 100a and a plurality of single process facilities 200a may be disposed along the longitudinal direction with respect to the substrate transfer apparatus 50a.

In the cluster-type substrate treatment system 10b in FIG. 6, a plurality of dual process facilities 100b and a plurality of single process facilities 200b may be disposed around an arcuate circumference of the substrate transfer apparatus 50b.

In the puritas-type substrate treatment system 10c in FIG. 7, a plurality of dual process facilities 100c and a plurality of single process facilities 200c may be disposed around a quadrangle circumference of the substrate transfer apparatus 50c.

Index modules 30a, 30b, and 30c may respectively include load ports 31a, 31b, and 31c and transfer frames 33a, 33b, and 33c.

A carrier in which the substrate W is stored may be seated in each of the load ports 31a, 31b, and 31c. The number of each of the load ports 31a, 31b, and 33c may be changed according to substrate treatment process efficiency, production efficiency, and so on. As an example, a Front Opening Unified Pod (FOUP) may be used as a carrier. A slot for horizontally storing a plurality of substrates W may be formed inside the carrier.

Each of the substrate transfer apparatus 50a, 50b, and 50c may be disposed between each of the dual process facilities 100a, 100b, and 100c and each of the single process facilities 200a, 200b, and 200c, thereby being capable of transferring the substrate to each apparatus.

In FIG. 5, the substrate transfer apparatus 50a may include a transfer chamber provided in the longitudinal direction, and may include a transfer robot 55a configured to transfer the substrate on the transfer chamber.

In FIG. 6, the substrate transfer apparatus 50b may include a transfer chamber having a circular shape, and may include a transfer robot 55b configured to transfer the substrate on the transfer chamber.

In FIG. 7, the substrate transfer apparatus 50c may include a transfer chamber having a quadrangle shape, and may include a transfer robot 55c configured to transfer the substrate on the transfer chamber.

Each of the dual process facilities 100a, 100b, and 100c may be disposed in contact with each transfer space of the substrate transfer apparatuses 50a, 50b, and 50c.

The dual process facilities 100a, 100b, and 100c may respectively include plasma process apparatuses 110a, 110b, and 110c configured to perform an adsorption process through plasma treatment, and may respectively include thermal treatment apparatuses 150a, 150b, and 150c configured to perform an etching process through thermal treatment. In the plasma process apparatuses 110a, 110b, and 110c and the thermal treatment apparatuses 150a, 150b, and 150C that are configured in the dual process facilities 100a, 100b, and 100c may be configured such that the number of plasma process apparatuses 110a, 110b, and 110c and the number of thermal treatment apparatuses 150a, 150b, and 150c are capable of being adjusted.

As an example, the number of plasma process apparatuses 110a, 110b, 110c and the number of thermal treatment apparatuses 150a, 150b, and 150c that are disposed in the dual process facilities 100a, 100b, and 100c may be determined according to a process time ratio between the adsorption process through the plasma treatment and the etching process through the thermal treatment.

For example, in a specific substrate treatment process, when the etching process and the adsorption process require similar process times, the plasma process apparatuses 110a, 110b, 110c, and the thermal treatment apparatuses 150a, 150b, and 150c may be disposed in the same number. In the specific substrate treatment process, when the etching process requires a process time of about two times more than a process time required to perform the adsorption process, the plasma process apparatuses 110a, 110b, 110c and the thermal treatment apparatuses 150a, 150b, and 150c may be disposed in a number ratio of 1:2.

One of the plasma process apparatuses 110a, 110b, and 110c and one of the thermal treatment apparatuses 150a, 150b, and 150c may correspond to each other and may be disposed adjacent to each other, or a plurality of plasma process apparatuses 110a, 110b, and 110c and a plurality of thermal treatment apparatuses 150a, 150b, and 150c may be mixed and disposed.

Each of the single process facilities 200a, 200b, and 200c may be disposed in contact with each transfer space of the substrate transfer apparatuses 50a, 50b, and 50c.

Each of the single process facilities 200a, 200b, and 200c may include each of substrate treatment apparatuses 210a, 210b, and 210c. The substrate treatment apparatuses 210a, 210b, and 210c may be configured to integrate and perform the adsorption process through the plasma treatment and the etching process through the thermal treatment.

The control apparatus 300 may schedule a substrate treatment process for the dual process facilities 100a, 100b, and 100c and the single process facilities 200a, 200b, and 200c, and may assign a substrate treatment process task to the dual process facilities 100a, 100b, and 100c and the single process facilities 200a, 200b, and 200c.

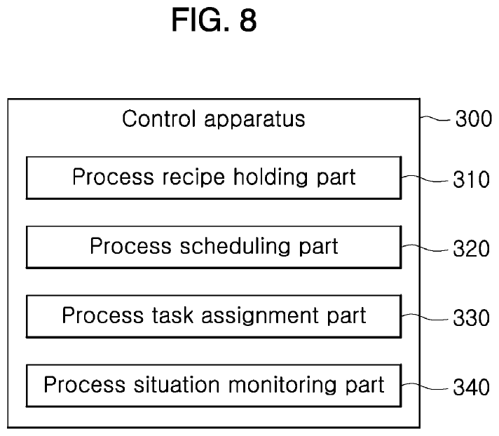

FIG. 8 is a view illustrating an embodiment of a control apparatus of the substrate treatment system according to the present disclosure.

The control apparatus 300 may include a process recipe holding part 310, a process scheduling part 320, a process task assignment part 330, a process situation monitoring part 340, and so on.

The process recipe holding part 310 may store a process recipe for a corresponding substrate. For example, for a specific substrate, the process recipe holding part 310 may have material information for a target process object, process gas information, thermal treatment time information, repetitive cycle information of the adsorption process and the etching process, and so on.

The process scheduling part 320 may determine a substrate treatment process task for a corresponding substrate on the basis of a process recipe. In addition, the process scheduling part 320 may schedule the substrate treatment process on the basis of the process recipe for the corresponding substrate by separating the dual process facility 100 and the single process facility 200. At this time, on the basis of the process recipe, the process scheduling part 320 may schedule which process gas is used, how much thermal treatment time is required, how many times the adsorption process and the etching process are repeated, and so on.

As an example, on the basis of the process recipe, the process scheduling part 320 may schedule the substrate treatment process by separating the dual process facility 100 and the single process facility 200 according to the type of process gas that is input during the plasma treatment of the corresponding substrate.

As an example, on the basis of the process recipe, the process scheduling part 320 may schedule the substrate treatment process by separating the dual process facility 100 and the single process facility 200 according to the thermal treatment process time for the corresponding substrate.

According to the process scheduling of the corresponding substrate, the process task assignment part 330 may assign the substrate treatment process task for the dual process facility 100 and for the single process facility 200.

The process situation monitoring part 340 may control the dual process facility 100 and the single process facility 200 such that the dual process facility 100 and the single process facility 200 each perform the corresponding substrate treatment process on the basis of the assigned substrate treatment process task. While the process situation monitoring part 340 controls the substrate treatment process task, the process situation monitoring part 340 may identify the progress of each substrate treatment process of the dual process facility 100 and the single process facility 200.

The process situation monitoring part 340 may determine a weighting of each substrate treatment task of the dual process facility 100 and the single process facility 200 on the basis of each process performance situation and each assigned substrate treatment task of the dual process facility 100 and the single process facility 200.

For example, when a relatively large number of substrate treatment process tasks are assigned to the dual process facility 100 and a relatively small number of substrate treatment process tasks are assigned to the single process facility 200, a relatively high weighting for the substrate treatment process task of the dual process facility 100 may be determined.

When the weighting is higher than a reference value, the process situation monitoring part 340 may request the process scheduling part 320 to reschedule the substrate treatment process task of a facility having a high weighting.

The process scheduling part 320 may reschedule a substrate treatment process task for the dual process facility 100 and for the single process facility 200 in consideration of the substrate treatment process task of the facility having a high weighting.

As an example, the process scheduling part 320 may reschedule the substrate treatment process task by performing bypassing such that the single process facility 200 performs a substrate treatment process task remaining during the repeated cycle process of the adsorption process and the etching process for the dual process facility 100 having a high weighting.

The process task assignment part 330 may determine appropriateness of rescheduling on the basis of the substrate treatment process task assigned to each of the dual process facility 100 and the single process facility 200.

For example, when the substrate treatment process time due to the rescheduling is more required than the substrate treatment process time due to the previous scheduling, the process task assignment part 330 may determine that the rescheduling is inappropriate.

When the rescheduling is determined to be appropriate, the process task assignment part 330 may assign the rescheduled substrate treatment process task to the dual process facility 100 and to the single process facility 200.

In addition, in the present disclosure, a substrate treatment method through the substrate treatment system according to the present disclosure described above is proposed. Hereinafter, a substrate treatment method according to the present disclosure will be described with reference to an embodiment.

Since the substrate treatment method according to the present disclosure is implemented through the substrate treatment system described above, an embodiment of the substrate treatment system will be referred to together.

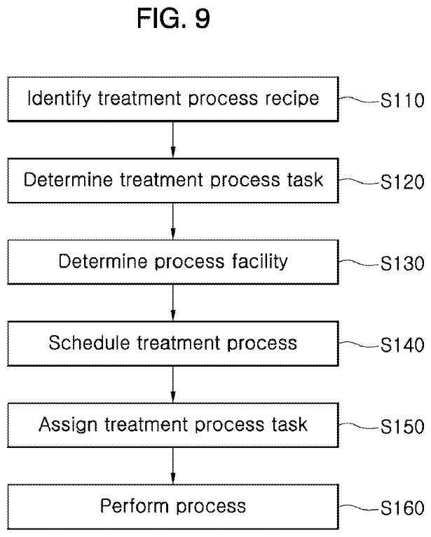

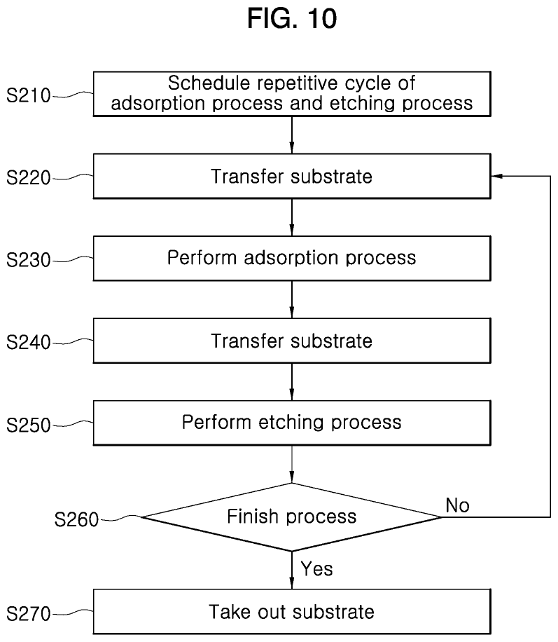

FIG. 9 is a flowchart illustrating an embodiment of the substrate treatment method according to the present disclosure.

The control apparatus 300 may identify a process recipe that is held for performing a process on the substrate S110, and may determine a substrate treatment process task S120.

As an example, on the basis of the process recipe, the control apparatus 300 may determine a substrate treatment process task for an input process gas, a substrate treatment process task for time required for the thermal treatment, and a substrate treatment process task for repeated cycling of the adsorption process and the etching process.

The control apparatus 300 may determine the process facility to perform the process on the basis of the substrate treatment process task S130. On the basis of the substrate treatment process task, the control apparatus 300 may distinguish between the dual process facility 100 and the single process facility 200, and may determine which process facility is appropriate to perform the corresponding substrate treatment process task.

As an example, the control apparatus 300 may determine the type of process gas that is input during the plasma treatment performed on the substrate, and may determine which of the dual process facility 100 and the single process facility 200 is appropriate to perform the substrate treatment process.

As an example, the control apparatus 300 may determine the thermal treatment process time for the substrate, and may determine which process facility among the dual process facility 100 and the single process facility 200 is suitable for performing the corresponding substrate treatment process task.

The control apparatus 300 may distinguish between the dual process facility 100 and the single process facility 200, and may schedule the substrate treatment process task that is to be performed by the corresponding process facility S140.

As an example, the control apparatus 300 may schedule a substrate treatment process task according to a repetitive cycle of the adsorption process and the etching process between the plasma process apparatus 110 and the thermal treatment apparatus 150 of the dual process facility 100.

As an example, the control apparatus 300 may schedule a substrate treatment process task according to a repetitive cycle of the adsorption process and the etching process in one substrate treatment apparatus 210 of the single process facility 200.

The control apparatus 300 may assign the substrate treatment process task to the dual process facility 100 or the single process facility 200 on the basis of the scheduling of the substrate treatment process task S150.

In addition, the control apparatus 300 may control the dual process facility 100 or the single process facility 200 so that the dual process facility 100 or the single process facility 200 each performs the assigned substrate treatment process task S160.

As an example, in relation to the performance of the substrate treatment process task of the dual process facility 100, FIG. 9 illustrates a flowchart illustrating an embodiment of the substrate treatment method using the dual process facility according to the present disclosure.

The control apparatus 300 may schedule the substrate treatment process task of the repetitive cycle of the adsorption process and the etching process through the dual process facility 100.

For example, the control apparatus 300 may transfer the substrate between the plasma process apparatus 110 and the thermal treatment apparatus 150 of the dual process facility 100, and may schedule the repetitive substrate treatment process task of the adsorption process and the etching process.

The control apparatus 300 may control the substrate transfer apparatus 50, the plasma process apparatus 110 and the thermal treatment apparatus 150 of the dual process facility 100 according to the scheduling of the substrate treatment process task.

The control apparatus 300 may transfer the substrate to the plasma process apparatus 110 of the dual process facility 100 by controlling the substrate transfer apparatus 50. The plasma process apparatus 110 of the dual process facility 100 may perform an adsorption process through the plasma treatment according to the assigned substrate treatment process task S230.

After the adsorption process is performed, the control apparatus 300 may transfer the substrate to the thermal treatment apparatus 150 of the dual process facility 100 by controlling the substrate transfer apparatus 50 S240. The thermal treatment apparatus 150 of the dual process facility 100 may perform the etching process through the thermal treatment according to the assigned substrate treatment process task S250.

While the control apparatus 300 monitors the process treatment situation, the control apparatus 300 may be control the process such that the repetitive cycle of the adsorption process and the etching process between the plasma process apparatus 110 and the thermal treatment apparatus 150 of the dual process facility 100 is performed.

The control apparatus 300 may determine whether the repetitive substrate treatment process of the adsorption process and the etching process is completed S260, and may transfer the substrate to the index module 30 when the substrate treatment process is completed S270.

In the present disclosure, the substrate treatment process task may be performed by distinguishing the dual process facility 100 and the single process facility 200 according to a type of process gas or a thermal treatment process time, and this process will be described through an embodiment.

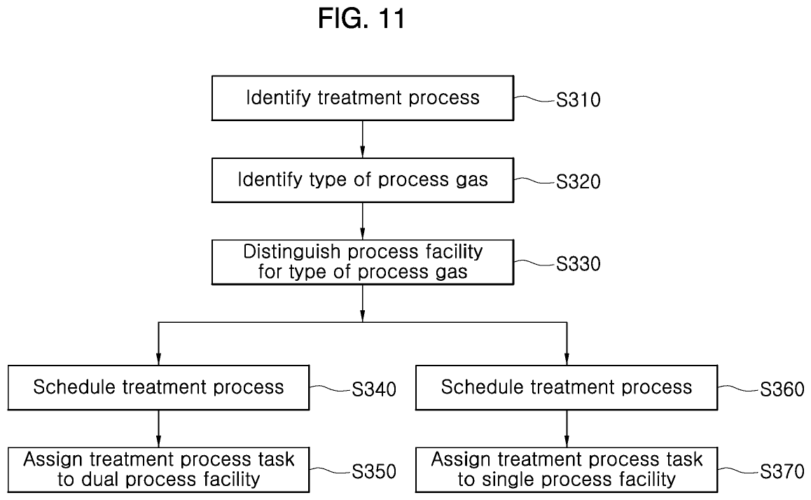

FIG. 11 is a view illustrating an embodiment of performing a substrate treatment process task by distinguishing a dual process facility and a single process facility according to a type of process gas in the substrate treatment method according to the present disclosure.

The control apparatus 300 may identify the substrate treatment process task on the basis of the process recipe S310, and may identify the type of process gas input in the adsorption process through the plasma treatment S320.

The control apparatus 300 may distinguish between the dual process facility 100 and the single process facility 200 to perform the substrate treatment process task according to the type of process gas that is input.

As an example, when plasma treatment is performed on the substrate by using a process gas that includes the CF-type process gas or the NF3 process gas, the control apparatus 300 may schedule the substrate treatment process task to be performed by the dual process facility 100 S340, and may assign the corresponding substrate treatment process task to the dual process facility 100 S350.

For example, in the substrate treatment apparatus 210 of the single process facility 200, the window 231 may be provided with quartz such that a heat source emitted from the heat source unit 260 is transferred to the substrate W. As a result, when a gas including a CF-type gas or a NF-type gas is used as a process gas, the window 231 is corroded. Therefore, when the plasma treatment is performed on the substrate by using the process gas that includes the CF-type gas or the NF3-type gas, the control apparatus 300 may assign the corresponding substrate treatment task to the dual process facility 100.

As an example, when the plasma treatment is performed on the substrate by using a process gas that includes the F-type process gas or the H-type process gas, the control apparatus 300 may schedule the substrate treatment process task to be performed by the single process facility 200 S360, and may assign the corresponding substrate treatment process task to the single process facility 200 S370.

For example, in the plasma process apparatus 110 of the dual process facility 100 described above, a part in contact with the process gas such as the wall part of the plasma process chamber 111 may be formed of a material such as aluminum ceramic (Al Ceramic). Therefore, when a gas including the F-type gas or the H-type gas is used as a process gas, the wall part of the plasma process chamber 111 and so on are corroded. Therefore, when the plasma treatment is performed on the substrate by using the process gas that includes the F-type gas or the H-type gas, the control apparatus 300 may assign the corresponding substrate treatment task to the single process facility 200.

As such, in the present disclosure, according to the type of process gas used in the plasma treatment process, the substrate treatment process may be performed by distinguishing the dual process facility 100 and the single process facility 200.

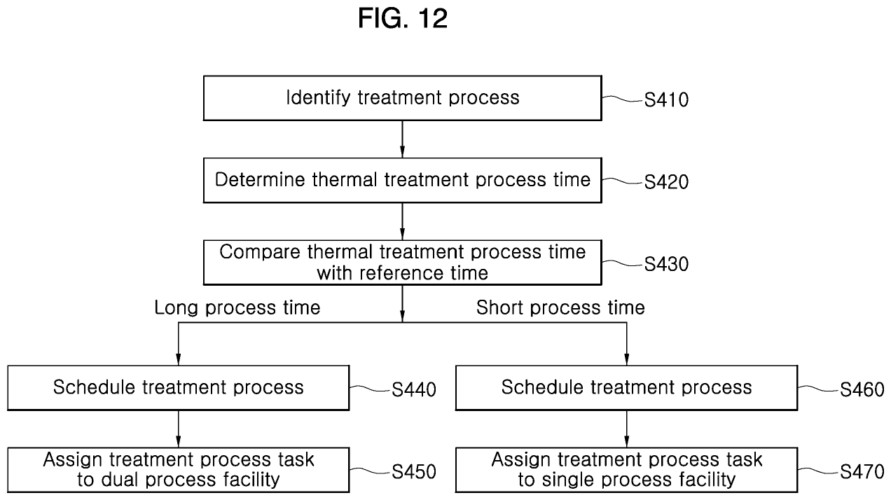

FIG. 12 is a view illustrating an embodiment of performing the substrate treatment process task by distinguishing the dual process facility and the single process facility according to a thermal treatment process time in the substrate treatment method according to the present disclosure.

The control apparatus 300 may identify the substrate treatment process task on the basis of the process recipe S410, and may identify the thermal treatment process time in the etching process through the plasma treatment S420.

The control apparatus 300 may compare the thermal treatment process time and a reference time to determine whether the thermal treatment process time is longer than a predetermined level or the thermal treatment process time is shorter than the predetermined level S340. The control apparatus 300 may distinguish between the dual process facility 100 and the single process facility 200 to perform the substrate treatment process task according to the thermal treatment process time.

The reference time may be appropriately set according to a process situation. For example, the reference time may be set to a longer time on the basis of the adsorption process time.

As an example, when the thermal treatment is performed on the substrate with a thermal treatment process time longer than the reference time, the control apparatus 300 may schedule the substrate treatment process task to be performed by the dual process facility 100 S440, and may assign the corresponding substrate treatment process task to the dual process facility 100 S450.

For example, a heat source using a lamp may be applied to the thermal treatment apparatus 150 of the dual process facility 100 so that the thermal treatment apparatus 150 is suitable for performing the heating process for a long time. That is, in the dual process facility 100, since the number of thermal treatment apparatuses 150 may be increased compared to the number of plasma process apparatuses 110, a substrate treatment process operation that requires a long time of the thermal treatment process is capable of being performed through the dual process facility 100.

Therefore, when the thermal treatment is performed on the substrate with the thermal treatment process time that is longer than the reference time, the control apparatus 300 may assign the corresponding substrate treatment process task to the dual process facility 100.

As an example, when the thermal treatment is performed on the substrate with a thermal treatment process time shorter than the reference time, the control apparatus 300 may schedule the substrate treatment process task to be performed by the single process facility 200 S460, and may assign the corresponding substrate treatment process task to the single process facility 200 S470.

Since the single process facility 200 integrates the adsorption process through the plasma treatment and the etching process through the thermal treatment in one substrate treatment apparatus 210, it is appropriate to perform the thermal treatment process relatively briefly compared to the thermal treatment process in the dual process facility 100. In addition, a heat source such as laser, microwaves, or the like may be used in the heat source unit 250 of the substrate treatment apparatus 210 so as to be suitable for performing the thermal treatment process through repeated control of such as a pulse waveform (PWM).

Therefore, when the thermal treatment is performed on the substrate with the thermal treatment process time that is shorter than the reference time, the control apparatus 300 may assign the corresponding substrate treatment process task to the single process facility 200.

Furthermore, in the present disclosure, while the substrate process situation of the dual process facility 100 and the single process facility 200 is monitored, the substrate treatment process may be bypassed and reassigned when the substrate treatment process task is excessively assigned to a specific process facility, and this process will be described through an embodiment.

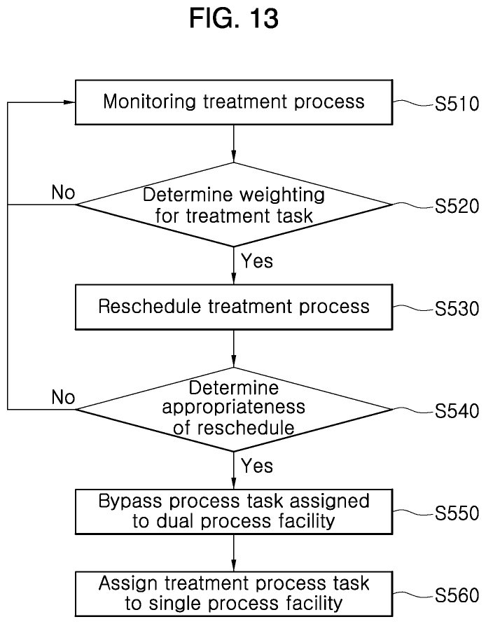

FIG. 13 is an example of bypassing the substrate treatment process task in the substrate treatment method according to the present disclosure.

While the control apparatus 300 monitors the substrate treatment process situation of the dual process facility 100 and the single process facility 200 S510, the control apparatus 300 may determine a weighting of each substrate treatment task of the dual process facility 100 and the single process facility 200 on the basis of each process performance situation and each assigned substrate treatment task of the dual process facility 100 and the single process facility 200 S520.

For example, when a relatively large number of substrate treatment process tasks are assigned to the dual process facility 100 and a relatively small number of substrate treatment process tasks are assigned to the single process facility 200, a relatively high weighting for the substrate treatment process task of the dual process facility 100 may be determined by the control apparatus 300.

When a weighting of the specific dual process facility 100 is higher than a reference value, the control apparatus 300 may reschedule the substrate treatment process task for the specific dual process facility 100 having the high weighting and the single process facility 200 S530.

For example, the control apparatus 300 may reschedule the substrate treatment process task of the specific dual process facility 100 having the high weighting to the substrate treatment process task of the single process facility 200 having a relatively low weighting.

The control apparatus 300 may determine appropriateness of rescheduling on the basis of the substrate treatment process task assigned to each of the dual process facility 100 and the single process facility 200.

For example, when the substrate treatment process time due to the rescheduling is more required than the substrate treatment process time due to the previous scheduling, the control apparatus 300 may determine that the rescheduling is inappropriate.

When the rescheduling is suitable, the control apparatus 300 may bypass the substrate treatment process task assigned to the specific dual process facility 100 having the high weighting S550, and may assign the substrate treatment process task to the single process facility 200 according to the rescheduling S560.

As an example, in a situation in which the adsorption process and the etching process are repeatedly performed between the plasma process apparatus 110 and the thermal treatment apparatus 150 of the dual process facility 100, the control apparatus 300 may bypass the remaining substrate treatment process task according to the rescheduling of the substrate treatment process task and may assign the remaining substrate treatment process task to the single process facility 200.

In the present disclosure, a Unit Per Hour (UPH) may be increased by assigning a substrate treatment process task by process characteristics through the substrate treatment system configured by combining the dual process facility that individually performs the adsorption process through the plasma treatment and the etching process through the thermal treatment and the single process facility that integrates and performs the adsorption process and the etching process.

Furthermore, in the present disclosure, the fine etching may be easily adjusted by separating and performing the adsorption process and the etching process from a separate apparatus or by integrating and performing the adsorption process and the etching process in one apparatus according to the process characteristics.

Although the embodiments of the present disclosure have been disclosed for illustrative purposes, those skilled in the art will appreciate that various modifications, additions, and substitutions are possible, without departing from the scope and spirit of the present disclosure. Accordingly, embodiments disclosed in the present disclosure are provided for describing the present disclosure and are not intended to limit the technical ideas of the present disclosure. The technical ideas of the present disclosure are not limited to the embodiments. The scope of the present disclosure should be construed as being covered by the scope of the appended claims, and all technical ideas falling within the scope of the claims should be construed as being included in the scope of the present disclosure.

What is claimed is:

1. A substrate treatment system comprising:
a dual process facility comprising at least one plasma process apparatus configured to perform an adsorption process on a substrate through plasma treatment and at least one thermal treatment apparatus configured to perform an etching process on the substrate through thermal treatment;
a substrate transfer apparatus configured to transfer the substrate between the plasma process apparatus and the thermal treatment apparatus; and
a control apparatus configured to schedule a substrate treatment process of a repetitive cycle of the adsorption process and the etching process and to assign a substrate treatment process task for the dual process facility,
wherein the dual process facility is configured such that a number of the at least one plasma process apparatus is determined and a number of the at least one thermal treatment apparatus is determined according to a process time ratio between the adsorption process and the etching process.

2. The substrate treatment system of claim 1, further comprising a single process facility comprising at least one substrate treatment apparatus configured to perform the adsorption process on the substrate through the plasma treatment and to perform the etching process on the substrate through the thermal treatment,
wherein the control apparatus is configured to schedule the substrate treatment process by distinguishing the dual process facility and the single process facility, and is configured to assign the substrate treatment process task to the dual process facility and the single process facility.

3. The substrate treatment system of claim 2, wherein the control apparatus is configured to schedule the substrate treatment process by distinguishing the dual process facility and the single process facility according to a type of process gas input during the plasma treatment of the substrate, and is configured to assign the substrate treatment process task to the dual process facility and the single process facility.

4. The substrate treatment system of claim 2, wherein the control apparatus is configured to schedule the substrate treatment process by distinguishing the dual process facility and the single process facility according to a thermal treatment process time of the substrate, and is configured to assign the substrate treatment process task to the dual process facility and the single process facility.

5. The substrate treatment system of claim 2, wherein the control apparatus is configured to determine a weighting of the substrate treatment process task assigned to each of the dual process facility and the single process facility, is configured to reschedule the substrate treatment process task assigned to each of the dual process facility and the single process facility on the basis of the weighting, and is configured to bypass the substrate treatment process task assigned to the dual process facility to the single process facility, thereby reassigning the substrate treatment process task.

6. The substrate treatment system of claim 1, wherein the plasma process apparatus of the dual process facility comprises:
a plasma process chamber providing a plasma treatment space for the substrate;
a substrate supporting unit configured to support the substrate;
a plasma generation unit configured to induce plasma on the plasma treatment space; and
a gas supply unit configured to supply a process gas to the plasma treatment space.

7. The substrate treatment system of claim 6, wherein the plasma process apparatus of the dual process facility further comprises an ion blocker disposed at an upper portion of the plasma treatment space of the plasma process chamber and configured to partition an upper plasma space and a lower plasma space, the ion blocker being configured to filter ions and to diffuse radicals.

8. The substrate treatment system of claim 1, wherein the thermal treatment apparatus of the dual process facility comprises:
a thermal treatment chamber providing a thermal treatment space for the substrate;
a substrate supporting unit configured to support the substrate;
a heat source unit disposed at an upper portion of the thermal treatment space and configured to provide a heat source for heating the substrate;
a cooling unit for cooling the substrate; and
a gas supply unit providing a process gas to the thermal treatment space.

9. The substrate treatment system of claim 2, wherein the at least one substrate treatment apparatus comprises:
a process chamber providing a treatment space for the substrate;
a substrate supporting unit configured to support the substrate;
a plasma generation unit configured to induce plasma on the treatment space;
a heat source unit disposed at an upper portion of the treatment space and configured to provide a heat source for heating the substrate;
a cooling unit for cooling the substrate; and
a gas supply unit configured to supply a process gas to the treatment space.

10. The substrate treatment system of claim 9, wherein the plasma generation unit comprises:
a transparent window disposed on the upper portion of the treatment space;
a transparent electrode formed on the transparent window; and
a power supply part configured to supply an RF power to the transparent electrode.

11. The substrate treatment system of claim 10, wherein the heat source unit is disposed on an upper portion of the transparent window of the plasma generation unit, and comprises a laser generator configured to heat the substrate by emitting laser or a microwave generator configured to heat the substrate by emitting microwaves.

12. A substrate treatment method comprising:
a process task assignment process in which a control apparatus schedules a substrate treatment process of a repetitive cycle of an adsorption process and an etching process on a substrate and assigns a substrate treatment process task to a plasma process apparatus and a thermal treatment apparatus of a dual process facility; and
a process performing process in which the control apparatus controls a substrate transfer apparatus so that the substrate is transferred between the plasma process apparatus and the thermal treatment apparatus of the dual process facility and the control apparatus controls the plasma process apparatus so that the adsorption process is performed and controls the thermal treatment apparatus so that the etching process is performed.

13. The substrate treatment method of claim 12 further comprising a treatment process determination process in which a type of a process gas input during plasma treatment on the substrate is determined,
wherein, in the process task assignment process, the substrate treatment process task is assigned by distinguishing the dual process facility and a single process facility according to the type of the process gas input during the plasma treatment on the substrate.

14. The substrate treatment method of claim 13, wherein, in the process task assignment process, when the plasma treatment on the substrate is performed by using a process gas containing a F-type (fluorine type) process gas or a H-type (hydrogen type) process gas, the substrate treatment process task is assigned to the single process facility.

15. The substrate treatment method of claim 13, wherein, in the process task assignment process, when the plasma treatment on the substrate is performed by using a process gas containing a CF-type (fluorocarbon type) process gas or a NF3-type (nitrogen trifluoride type) process gas, the substrate treatment process task is assigned to the dual process facility.

16. The substrate treatment method of claim 12, further comprising a treatment process determination process in which a thermal treatment process time on the substrate is determined, wherein, in the process task assignment process, the substrate treatment process task is assigned by distinguishing the dual process facility and a single process facility according to the thermal treatment process time on the substrate.

17. The substrate treatment method of claim 16, wherein, in the process task assignment process, when thermal treatment on the substrate is performed with the thermal treatment process time shorter than a reference time, the substrate treatment process task is assigned to the single process facility.

18. The substrate treatment method of claim 16, wherein, in the process task assignment process, when thermal treatment on the substrate is performed with the thermal treatment process time longer than a reference time, the substrate treatment process task is assigned to the dual process facility.

19. The substrate treatment method of claim 12, further comprising:
a process situation monitoring process in which a substrate treatment process performance situation of each of the dual process facility and a single process facility is monitored;
a weighting determination process in which a weighting for a substrate treatment task of each of the dual process facility and the single process facility is determined on the basis of the substrate treatment process performance situation and the substrate treatment process task assigned for each of the dual process facility and the single process facility;
a rescheduling process in which the substrate treatment process task for the dual process facility having a relatively high weighting and for the single process facility having a relatively low weighting is rescheduled; and
a process treatment task reassignment process in which the substrate treatment process task of the dual process facility is bypassed and assigned to the single process facility.

20. A substrate treatment system comprising:
a dual process facility comprising at least one plasma process apparatus configured to perform an adsorption process on a substrate through plasma treatment and at least one thermal treatment apparatus configured to perform an etching process on the substrate through thermal treatment, the dual process facility being configured such that a number of plasma process apparatuses is determined and a number of thermal treatment apparatuses is determined according to a process time ratio between the adsorption process and the etching process;
a single process facility comprising at least one substrate treatment apparatus configured to perform the adsorption process on the substrate through the plasma treatment and to perform the etching process on the substrate through the thermal treatment;
a substrate transfer apparatus configured to transfer the substrate to the plasma process apparatus and the thermal treatment apparatus of the dual process facility and to the at least one substrate treatment apparatus of the single process facility; and
a control apparatus configured to schedule a substrate treatment process by distinguishing the dual process facility and the single process facility, to assign a substrate treatment process task by distinguishing the dual process facility and the single process facility according to a type of a process gas input during the plasma treatment and a thermal treatment process time on the substrate, to determine a weighting for a substrate treatment task assigned to each of the dual process facility and the single process facility, and to reassign the substrate treatment task by bypassing the substrate treatment task assigned to the dual process facility to the single process facility on the basis of the weighting.
